(19) United States
(12) Patent Application Publication
(10) Pub. No.: US 2013/0162268 A1
(43) Pub. Date: Jun. 27, 2013

(54) Measurement Transmitter with at least one Inductive Interface

(71) Applicant: Endress + Hauser Conducta Gesellschaft fur Mess- und Regeltechnik mbH + Co. KG, Gerlingen (DE)

(72) Inventors: Torsten Pechstein, Radebeul (DE); Sven-Matthias Scheibe, Dresden (DE); Stefan Pilz, Bad Lausick (DE)

(73) Assignee: Endress + Hauser Conducta Gesellschaft fur Mess- und Regeltechnik mbH + Co. KG, Gerlingen (DE)

(21) Appl. No.: 13/719,831

(22) Filed: Dec. 19, 2012

(30) Foreign Application Priority Data
Dec. 27, 2011 (DE) 10 2011 089 944.8

(51) Int. Cl. G01R 27/26

(52) U.S. Cl. CPC G01R 27/2611
USPC 324/654

(57) ABSTRACT

A measurement transmitter for receiving and processing measurement data, comprising: a transmitter housing with at least one circuit chamber within the transmitter housing, an electronic circuit, which is arranged in the circuit chamber, for the supply of a sensor and for receiving and processing of measurement data of the sensor via at least one inductively coupling interface, wherein, the inductively coupling interface comprises a plug-in connecting coupling with a first plug-in coupling element on a primary side and a complimentary second plug-in connection element on a secondary side, wherein, the second plug-in connection element is detachably connectable to the first plug-in connection element, and wherein, the first plug-in connection element comprises at least a first inductive coupler in a coupling housing, which is formed hermetically sealed, in particular substance-to-substance bonded to, or formed integrally with, the transmitter housing.

The present invention relates to a measurement transmitter with at least one inductively coupling interface. Inductively coupling interfaces are advantageous in that they avoid the problems of galvanically coupling interfaces such as corrosion, electrical discharge (sparking) or leakage currents in moist environments. This is especially relevant for potentiometric sensors.

The European patent EP 1 206 012 B1 protects an arrangement comprising a pH sensor with one such inductively coupling interface for connecting to a measurement transmitter pH-sensor and a plug-in connector, where a transmission cable can be connected to the pH sensor by means of the plug-in connector, whereby a power supply signal can be transmitted to the pH sensor, and a measuring signal can be contactlessly transmitted from the pH sensor via the plug-in connector, the plug-in connector that comprises a plug-in element and a socket element, which can be detachably connected to the plug-in element, for connecting the transmission cable to the pH sensor, whereby either the plug-in element is assigned to the pH sensor and the socket element is assigned to the transmission cable, or the socket element is assigned to the pH sensor and the plug-in element is assigned to the transmission cable, wherein no electrical contact elements lead out of the socket element and the plug-in element, wherein the socket element is completely sealed to the outside, the plug-in element is completely sealed to the outside and the plug-in connector comprises units for inductive signal transmission between the plug-in element and the socket element.

The patent publication DE 102 20 450 discloses a connection cable with an inductive primary side plug-in element and an inductively coupling secondary side plug-in element. The patent publication teaches that, especially in moist and chemically active environments, there are high requirements placed on the housings of contacts in terms of their impermeability and electrical isolation properties, whereby in the case of galvanic contacts, a perfect protection is in practice not to be achieved. Therefore, the patent publication proposes inductively coupling plug-in elements, which each comprise hermetically sealed interface housing. The transmission cable is to be connected between complementary coupling elements, which are arranged, by way of example, on a sensor and a superordinate unit, such as a measurement transmitter for example.

The patent publication DE 10 2008 043 297 A1 discloses, in the context of the previously described technology, an interface neutral function module, which can be embodied in each case with a primary side and secondary side inductively coupling interface, and which is in particular hermetically sealed and without a breach in the housing. The function module comprises an energy storing unit for supplying a secondary side connected sensor, for the case where the normally applied primary side energy supply fails. In an embodiment of the invention, the function module comprises a data logger for plotting secondary side recorded data, a display unit and operational elements.

The patent publication DE 10 2008 053 920 A1 discloses a distribution module that comprises a housing, module electronics, a first connection apparatus for a first measuring device, a second connection apparatus for a second measuring device, and at least a third connection apparatus for at least one data processing unit, whereby the first connection apparatus and the second connection apparatus, each comprise transmission coils that are placed within the housing and that are connected to the module electronics for forming an inductively coupling interface, and whereby each of the at least two transmission coils is placed inside of the plug-in element.

For control of the distribution module, in particular of the first connection apparatus and second connection apparatus as well and/or for processing control commands received via a third connection apparatus, the patent publication DE 10 2008 053 920 A1 discloses a control unit formed by means of a microprocessor (μC), and/or a modifiable logic component (field programmable gate array, FPGA), and/or an application specific integrated circuit (ASIC). The patent publication DE 10 2008 053 920 A1 furthermore discloses a display apparatus, which communicates with the control unit, for visualizing data transmitted via the distribution module and/or for visualizing status information relating to the distribution module, e.g. also present connection configurations on connection apparatuses of the distribution module and/or data streams flowing via a connection apparatus, as well as a service unit, which communicates with the control unit, as well as for programming the control unit and for selectively switching connection apparatuses of the distribution module on or off, respectively, by way of example, and a wireless communication apparatus, which communicates with the control unit, provided for wireless sending and receiving of configuration data for the distribution module.

Furthermore, the patent publication DE 10 2008 053 920 A1 discloses data storage that communicates with and is integrated into the control unit, respectively, such as an EEPROM, PROM or a hard drive, for storing measurement variables and information, respectively, that is from the distribution module and related to measuring devices, respectively, such as, by way of example, for storing measurement values, calibration data, unlock codes, certificates, data for enabling operation, parameterization data or authentication data.

Furthermore, the patent publication DE 10 2008 053 920 A1 discloses that at least the two connection apparatuses, which are provided for the measurement devices and identical to each other, comprise, at the distribution module, transmission coils, which are each placed within the module housing and are connected to the module electronics and for forming an electrical energy transmitting inductively coupling interface between the respective measuring device and the distribution module. Each of the at least two transmission coils is placed inside of a plug-in connection element, which is composed of electrically non conducting artificial material, serves to form an detachable plug-in connection coupling and is embodied as an integral part of the module housing. Furthermore, the third connection apparatus, provided for the data processing unit, can also comprise a transmission coil placed, for the purpose of forming an inductive interface between the distribution module and data processing unit, within the plug-in connection element, which, is composed of electrically non conducting artificial material, serves to form an detachable plug-in connection coupling and is embodied as an integral part of the module housing. In the event that the interfaces formed in this way are exclusively inductively coupling in nature, a galvanic separation of measurement device and distribution module, and as the case may be, of distribution module and data processing unit, can be achieved by very simple means. So, by simple means, a distribution module with liquid-tight interfaces can be realized, which require no extruding electrical contact elements for making an electrical connection between measuring device and distribution module.

The company ‘Knick’ proffers a measurement transmitter under the designation ‘Portavo’, whose housing satisfies the IP rating IP 67. In the housing, demand dependent measurement modules are employed for various operating modes, wherein these modules are not protected from moisture by the housing. A measurement module for an inductively coupling interface of the so called ‘Memosens’ technology is available, wherein this measurement module comprises a multipolar connection socket with galvanic contacts that a plug with corresponding connection pins is to be inserted into. A protection of the contacts against moisture is not provided.

As a result, the connection elements with inductively coupling interfaces comprise sealed housings if they are provided for a direct connection to a sensor. This makes sense as far as it goes because the greatest damage to the interface as a result of cleaning chemicals or the process medium is to be expected in the immediate proximity of the sensor at the place of measurement.

However, exposed galvanic contacts are present on measurement transmitters for connecting the sensors or sensor cables are fed into the measurement transmitter housing via Panzergewinde (German technical standard for the threading of a cable gland), which comprise appropriate sealing casings. Thus, on the one hand this means increased installation costs with associated risks such as reversal of the polarity at the cabling connections, and on the other hand, the connections and, as the case may be, the circuit components of the measurement transmitter are still only given limited protection. It is therefore the object of the present invention to find a remedy for this and to furnish a safe measurement transmitter for explosion prone areas.

The object is achieved according to the invention by means of a measurement transmitter according to the independent claim 1.

The inventive measurement transmitter comprises a transmitter housing with at least one circuit chamber within the transmitter housing, an electronic circuit, which is arranged in the circuit chamber, for the supply of a sensor and for receiving and processing measurement data of the sensor via at least one inductively coupling interface, wherein, the inductively coupling interface comprises a plug-in connecting coupling with first plug-in coupling element on a primary side, and a complimentary second plug-in connection element on a secondary side, wherein, the second plug-in connection element is detachably connectable to the first plug-in connection element, wherein, the first plug-in connection element comprises at least one first inductive coupler in a coupling housing, which is formed hermetically sealed, in particular substance-to-substance bonded to, or formed integrally with, the transmitter housing.

In an embodiment of the invention, the measurement transmitter satisfies the IP ratings IP67, IP 68, IP 69, and in particular IP 69k.

In an embodiment, the measurement transmitter comprises, in each case, a plug-in connection element of two or more inductively coupling interfaces, wherein the inductively coupling interface, in each case, comprises a plug-in connecting coupling with a first plug-in coupling element and a complimentary second plug-in connection element, wherein, in each case, the second plug-in connection element is detachably connectable to the first plug-in connection element, wherein, in each case, the first plug-in connection element comprises at least a first inductive coupler in a coupling housing, which is formed hermetically sealed, in particular substance-to-substance bonded to, or formed integrally with, the transmitter housing.

Connected sensors and actuators, respectively, can be supplied with energy via the inductively coupling interface and a unidirectional or bidirectional data exchange can occur with them.

The measurement transmitter can be, according to protocol, connected directly or indirectly to the process control system via an additional inductive interface that is preferably embodied as the other inductive interfaces are, or as the case may be, via an interface with galvanic plug elements, which are preferably sealable.

The measurement transmitter comprises, according to an embodiment of the invention, a display unit whose display is hermetically sealed and in particular substance-to-substance bonded to, and integrated in, the housing.

The measurement transmitter comprises, according to an embodiment of the invention, an operating apparatus whose operating elements are hermetically sealed and in particular substance-to-substance bonded to, and integrated in, the housing. The operating elements can in particular comprise REED contacts that can be magnetically activated and Hall-sensors or capacitive sensors, which can be activated through the housing wall.

The invention will now be explained with the help of the embodiments depicted in the figures.

They show:

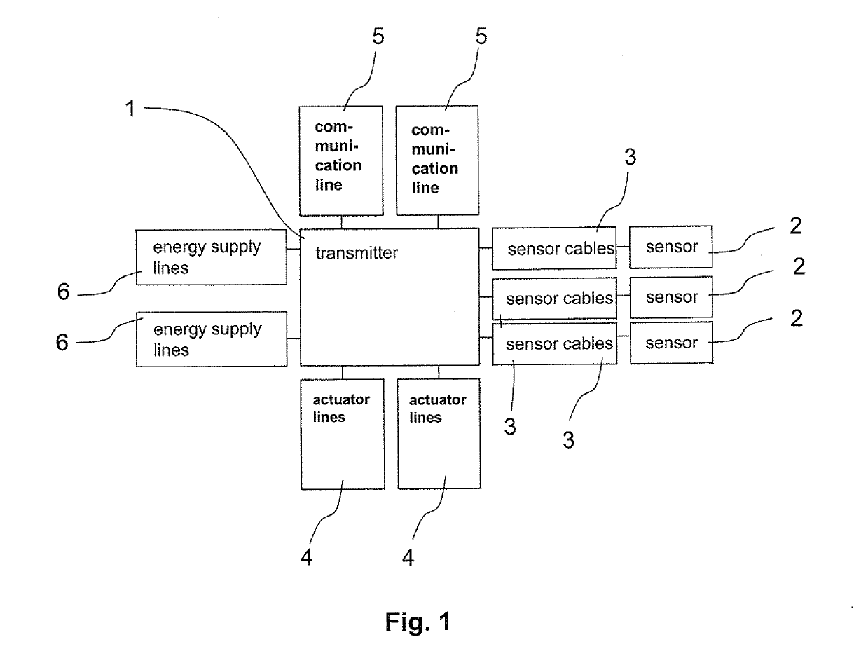

FIG. 1: Measurement site configuration with an inventive transmitter;

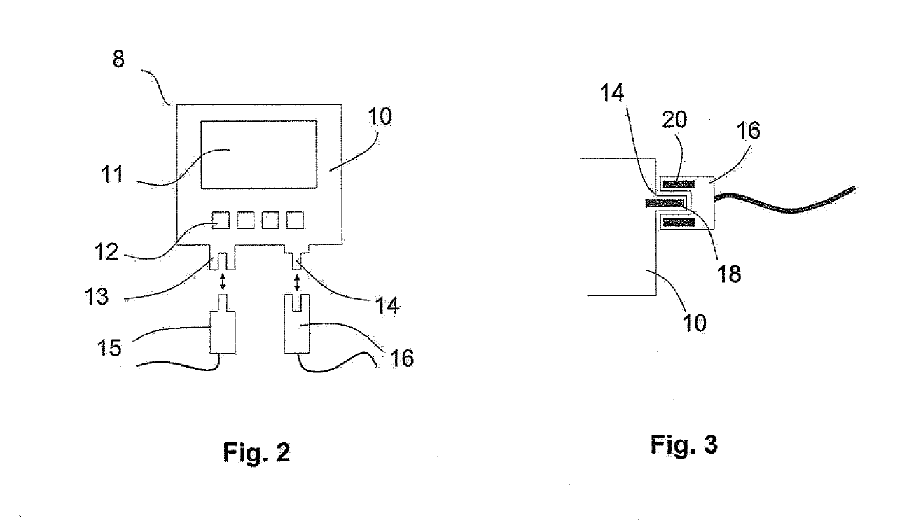

FIG. 2: A schematic frontal view of an embodiment of an inventive measurement transmitter; and

FIG. 3: An interface of an inventive measurement transmitter.

The measurement site configuration shown in FIG. 1 comprises a measurement transmitter 1 with a hermetically sealed housing, which comprises hermetically sealed interfaces in the same way, which comprise, in particular, inductively coupling plug-in connection couplings. Field devices, i.e. sensors 2 and actuators, are connected to these interfaces via inductively coupling sensor cables 3 and actuator lines 4.

Communication lines 5, for the communication of the measurement transmitter with other components of a control system, are connected via hermetically sealed interfaces, which can also be, by way of example, inductively coupling interfaces.

The energy supply of the measurement transmitter 1 occurs via one or more energy supply lines 6, wherein, in a preferable embodiment, the energy is inductively coupling in the measurement transmitter, or is led via plug-and-sockets and fused in the housing of the measurement transmitter, respectively.

The measurement transmitter 8 in depicted in FIG. 2 comprises a hermetically sealed housing 10, an inductively coupling plug-in connection element 13 for the connection to a process control system and an inductively coupling plug-in connection element 14 for the connection of a sensor to the measurement transmitter. The plug-in connection elements 13, 14 are embodied so that a permutation of the counter pieces 15, 16 is not possible. As it is, it is only ever possible for the proper counter piece 15, 16 to be connected to the plug-in connection element of the measurement transmitter 8. HART, Profibus, Foundation Fieldbus, or another bus system can come into operation as a protocol for the interface to the process control system. The connection to the sensor can occur by means of the so called Memosens technology. The measurement transmitter 8 further comprises a display field 11 whose display window is embodied so as to be substance-to-substance bonded with the housing 10, just like the operating elements 12, which, by way of example, can comprise capacitive touch sensors.

FIG. 3 shows, prototypically, the integral embodiment of the inductively coupling plug-in connection element 14 in the wall of the housing 10 of the measurement transmitter 8 from FIG. 2. The plug-in connection element 14 comprises a central, primary side, inductive coupler 18 that is arranged in the contour, which is embodied monolithically with or is substance-to-substance bonded to the housing wall, and which corresponds to a primary side plug-in connection element of the Memosens technology. A secondary side counter piece can be attached to this contour, where the secondary side inductive coupler 20 circumferentially encompasses the primary side inductive coupler 18.

1-8. (canceled)

9. A measurement transmitter for receiving and processing measurement data, comprising:
at least one inductively coupling interface;
a transmitter housing with at least one circuit chamber within said transmitter housing;
an electronic circuit, which is arranged in said at least one circuit chamber, for the supply of a sensor and for receiving and processing measurement data of said sensor via said at least one inductively coupling interface, wherein:
said at least one inductively coupling interface comprises a plug-in connecting coupling with a first plug-in connection element on a primary side, and a complimentary, second plug-in connection element on a secondary side;
said second plug-in connection element is detachably connectable to said first plug-in connection element; and
said first plug-in connection element comprises at least a first inductive coupler in a first coupler housing, which is hermetically sealed, in particular substance-to-substance bonded to, or formed integrally with, said transmitter housing.

10. The measurement transmitter according to claim 9, wherein:
the measurement transmitter satisfies the IP ratings IP67, IP 68, IP 69, or IP 69k.

11. The measurement transmitter according to claim 9, which in each case comprises a plug-in connection element of two or more inductively coupling interfaces, wherein:
said at least one inductively coupling interface in each case comprises a plug-in connecting coupling with a first plug-in connection element on a primary side, and a complimentary, second plug-in connection element on a secondary side;
in each case, the second plug-in connection element is detachably connectable to the first plug-in connection element; and
in each case, the first plug-in connection element comprises at least a first inductive coupler in a first coupler housing, which is hermetically sealed, in particular substance-to-substance bonded to, or formed integrally with, the transmitter housing.

12. The measurement transmitter according to claim 9, further comprising:
an interface via which the measurement transmitter is connectable to a process control system, wherein:
the measurement transmitter communicates with the process control system via said interface.

13. The measurement transmitter according to claim 12, wherein:
said interface comprises galvanic contacts.

14. The measurement transmitter according to claim 13, wherein:
said interface is an inductively coupling interface, said inductively coupling interface comprises a plug-in connecting coupling with a first plug-in connection element on a primary side, and a complimentary, second plug-in connection element on a secondary side;
the second plug-in connection element is detachably connectable to the first plug-in connection element;
the first plug-in connection element comprises at least a first inductive coupler in a coupling housing, which is formed hermetically sealed, in particular substance-to-substance bonded to, or formed integrally with, the transmitter housing.

15. The measurement transmitter according to claim 9, further comprising:
a display unit whose display is hermetically sealed and in particular substance-to-substance bonded, and integrated, in said housing.

16. The measurement transmitter according to claim 9, further comprising:
an operating device whose operating elements are hermetically sealed, in particular substance-to-substance bonded and integrated in said housing.
